(19) United States
(12) Patent Application Publication
(10) Pub. No.: US 2017/0062387 A1
(43) Pub. Date: Mar. 2, 2017

(54) SEMICONDUCTOR CHIP, SEMICONDUCTOR PACKAGE INCLUDING THE SAME, AND METHOD OF FABRICATING THE SAME

(71) Applicant: Samsung Electronics Co., Ltd., Suwon-si (KR)

(72) Inventors: Seokwoo HONG, Seongnam-si (KR); Sang-ki KIM, Yongin-si (KR); Kyo-Seon CHOI, Hwaseong-si (KR); Ae-Hee CHOI, Yongin-si (KR)

(73) Assignee: Samsung Electronics Co., Ltd., Suwon-si (KR)

(21) Appl. No.: 15/204,432

(22) Filed: Jul. 7, 2016

(30) Foreign Application Priority Data
Aug. 26, 2015 (KR) 10-2015-0120336

(51) Int. Cl. H01L 25/065; H01L 25/00

(52) U.S. Cl. CPC H01L 25/0657; H01L 25/50; H01L 2225/06506; H01L 2225/06555; H01L 2225/06586

(57) ABSTRACT

The semiconductor chip may include an integrated circuit on a substrate, center pad on the substrate and electrically connected to the integrated circuit, lower insulating structure on the center pad and having a contact hole exposing the center pad, redistribution layer including a conductive pattern and a barrier pattern, the barrier pattern between the lower insulating structure and the conductive pattern, the conductive patter including a contact portion filling the contact hole, bonding pad portion, and conductive line portion on the lower insulating structure and connecting the contact portion to the bonding pad portion, and an upper insulating structure on the redistribution layer and having a first opening defined therein, the first opening exposing the bonding pad portion. The upper insulating structure may include an upper insulating layer covering the lower insulating structure and the redistribution layer and a polymer layer on the upper insulating layer.

### CROSS-REFERENCE TO RELATED APPLICATIONS

This U.S. non-provisional patent application claims priority under 35 U.S.C. §119 to Korean Patent Application No. 10-2015-0120336, filed on Aug. 26, 2015, in the Korean Intellectual Property Office, the entire contents of which are hereby incorporated by reference.

### BACKGROUND OF THE INVENTION

This disclosure relates to semiconductor chips with a redistribution layer, semiconductor packages including the same, and/or methods of fabricating the same.

Due to their small-size, multi-functionality, and/or low-cost characteristics, semiconductor devices are widely adopted in the electronic industry. Generally, semiconductor devices are classified into a memory device for storing data, a logic device for processing data, and a hybrid device for performing various functions.

As the electronic industry advances, there is an increasing demand for a semiconductor device with a higher integration density and higher performance. One possible approach to meet such a demand, is reducing a process margin (for example, in a photolithography process). However, the reduction of the process margin may lead to other challenges in fabricating a semiconductor device.

In the meantime, various package technologies have been developed to meet demands for larger capacity, thinner thickness, and smaller size of semiconductor devices and/or electronic appliances. For example, a package technology of vertically stacking semiconductor chips has been used to allow an electronic product to have higher density and larger capacity features. This package technology allows many semiconductor chips to be stacked on a reduced area, compared to a package with a single semiconductor chip.

### SUMMARY

Some example embodiments of the inventive concepts provide a semiconductor chip with a redistribution layer formed using a deposition and patterning process.

Some example embodiments of the inventive concepts provide a method of fabricating a semiconductor chip with a redistribution layer, using a deposition and patterning process.

Some example embodiments of the inventive concepts provide a semiconductor package, in which a semiconductor chip with a redistribution layer is provided.

According to an example embodiment, a semiconductor chip includes an integrated circuit on a substrate, a center pad on the substrate and electrically connected to the integrated circuit, a lower insulating structure on the center pad, the lower insulating structure having a contact hole exposing the center pad, the lower insulating structure including a plurality of lower insulating layers sequentially stacked on the substrate, a redistribution layer including a conductive pattern and a barrier pattern, the barrier pattern between the lower insulating structure and the conductive pattern, the conductive pattern including a contact portion, a bonding pad portion, and a conductive line portion, the contact portion filling the contact hole, the conductive line on the lower insulating structure and connecting the contact portion to the bonding pad portion, and an upper insulating structure on the redistribution layer, the upper insulating structure having a first opening defined therein, the first opening exposing the bonding pad portion, the upper insulating structure including an upper insulating layer and a polymer layer, the upper insulating layer covering the lower insulating structure and the redistribution layer, the polymer layer on the upper insulating layer.

According to an example embodiment, a semiconductor package includes a package substrate, and at least one semiconductor chip on the package substrate and electrically connected to the package substrate through a wire, the at least one semiconductor chip having a first surface facing the package substrate and a second surface opposite to the first surface, a center pad on the second surface, a lower insulating structure having a contact hole exposing the center pad, the lower insulating structure including a plurality of sequentially-stacked lower insulating layers, a conductive pattern including a contact portion, a conductive line portion, and a bonding pad portion, the contact portion filling the contact hole, the bonding pad portion in contact with the wire, and a conductive line portion on the lower insulating structure and connecting the contact portion to the bonding pad portion, and an upper insulating structure on the conductive pattern, the upper insulating structure having an opening defined therein, the opening exposing the bonding pad portion, the upper insulating structure including an inorganic insulating layer on the lower insulating structure and the conductive pattern, the inorganic insulating layer containing silicon, and a polymer layer on the inorganic insulating layer.

According to an example embodiment, a method of fabricating a semiconductor chip includes forming a center pad and integrated circuit on a substrate such that the center pad is electrically connected to an integrated circuit, forming a lower insulating structure on the semiconductor chip to cover the center pad, the lower insulating structure including one or more lower insulating layers, patterning the lower insulating structure to form a contact hole exposing the center pad, forming a conductive layer on the lower insulating structure and the contact hole, patterning the conductive layer to form a conductive pattern on the lower insulating structure, the conductive pattern filling at least a portion of the contact hole, the conductive pattern extending in a direction and including a bonding pad portion, forming an upper insulating structure on the conductive pattern and the lower insulating structure, the upper insulating structure including an upper insulating layer and a polymer layer, the upper insulating layer covering the lower insulating structure and the conductive pattern, the polymer layer on the upper insulating layer, and patterning the upper insulating structure to form an opening exposing the bonding pad portion.

According to an example embodiment, a semiconductor package includes a package substrate, a semiconductor chip on the package substrate and having a chip pad electrically connected to an integrated circuit and exposed through a lower insulating structure, a redistribution pattern including aluminum, the redistribution pattern connected to the chip pad at around a first end portion thereof and extending on the lower insulating structure, and an upper insulating structure on the redistribution pattern and the lower insulating structure, the upper insulating structure including an opening at around a second end portion of the redistribution pattern, the opening exposing the redistribution pattern therethrough, the second end portion being opposite to the first end portion, a portion of the redistribution pattern exposed by the opening functioning as a pad portion, and a wire connecting the exposed portion of the redistribution pattern of the semiconductor chip to the package substrate. The lower insulating structure is between a chip substrate and the conductive pattern. The lower insulating structure has a recess region formed in an upper portion thereof. When viewed in a plan view, the recess region is not overlapped with the conductive pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor package according to an example embodiment of the inventive concepts.

FIG. 2 is a plan view schematically illustrating a second surface of a first semiconductor chip according to an example embodiment of the inventive concepts.

FIG. 3 is a sectional view of sections, which are respectively taken along lines I-I′ and II-II′ of FIG. 2, and illustrates a first semiconductor chip according to an example embodiment of the inventive concepts.

FIG. 4 is an enlarged sectional view of a region M of FIG. 3.

FIGS. 5 through 9 are sectional views, each of which illustrates sections taken along lines I-I′ and II-II′ of FIG. 2, and illustrate a method of fabricating a first semiconductor chip according to an example embodiment of the inventive concepts.

FIG. 10 is a sectional view of sections, which are respectively taken along lines and II-II′ of FIG. 2, and illustrates a first semiconductor chip according to an example embodiment of the inventive concepts.

FIG. 11 is a sectional view of sections, which are respectively taken along lines I-I′ and II-II′ of FIG. 2, and illustrates a first semiconductor chip according to an example embodiment of the inventive concepts.

FIG. 12 is a sectional view illustrating a semiconductor package according to some example embodiments of the inventive concepts.

FIG. 13A is a sectional view of sections, which are respectively taken along lines I-I′ and II-II′ of FIG. 2, and illustrates a first semiconductor chip according to some embodiments of the inventive concept.

FIG. 13B is an enlarged sectional view of a region N of FIG. 13A.

It should be noted that these figures are intended to illustrate the general characteristics of methods, structure and/or materials utilized in certain example embodiments and to supplement the written description provided below. However, these drawings are not to scale and may not precisely reflect the precise structural or performance characteristics of any given example embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Various example embodiments of the inventive concepts will now be described more fully with reference to the accompanying drawings, in which example embodiments are shown. Example embodiments of the inventive concepts may, however, be embodied in many different forms and should not be construed as being limited to the example embodiments set forth herein; rather, these example embodiments are provided so that this disclosure will be thorough and complete, and will fully convey the concepts of example embodiments to those of ordinary skill in the art.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

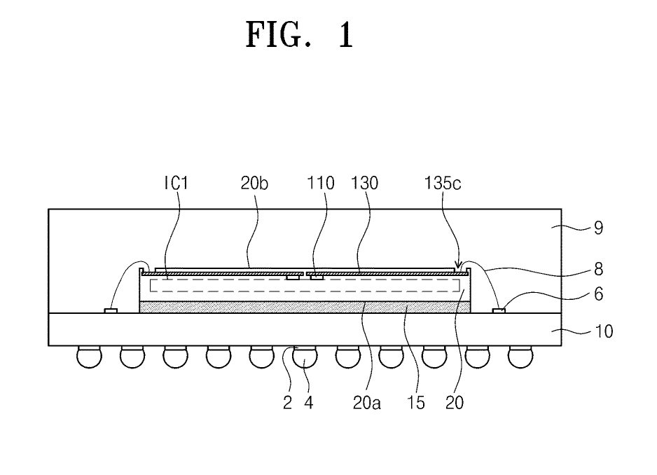

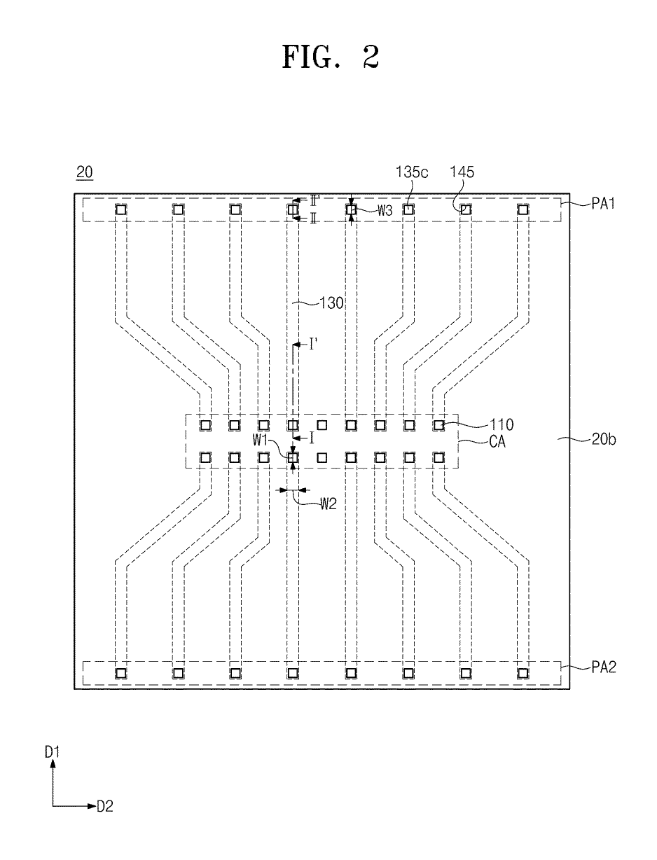

FIG. 1 is a sectional view illustrating a semiconductor package according to an example embodiment of the inventive concepts. FIG. 2 is a plan view schematically illustrating a second surface of a first semiconductor chip according to an example embodiment of the inventive concepts.

Referring to FIGS. 1 and 2, a first semiconductor chip 20 may be mounted on a package substrate 10. As an example, the package substrate 10 may be a printed circuit board (PCB). The package substrate 10 may include circuit patterns (not shown) provided on one or both of top and bottom surfaces thereof. At least one of the circuit patterns may be electrically connected to first outer pads 2, which may be provided on the bottom surface of the package substrate 10, Outer terminals 4 (e.g., solder bumps or solder balls) may be respectively attached on the first outer pads 2 to electrically connect the package substrate 10 to an external device. At least one other of the circuit patterns may be electrically connected to second outer pads 6, which may be provided on the top surface of the package substrate 10.

The first semiconductor chip 20 may have a first surface 20a facing the package substrate 10 and a second surface 20b facing the first surface 20a. The first semiconductor chip 20 may include a center area CA and first and second peripheral areas PA1 and PA2. The center area CA may be positioned at a region including a center of the second surface 20b of the first semiconductor chip 20. The first and second peripheral areas PA1 and PA2 may be positioned adjacent to opposite sides of the first semiconductor chip 20, respectively. The center area CA may be disposed between the first and second peripheral areas PA1 and PA2.

The first semiconductor chip 20 may include a first integrated circuit IC1, center pads 110, and redistribution layers 130. The first integrated circuit IC1 may be provided in a portion of the first semiconductor chip 20 positioned adjacent to the second surface 20b. The center pads 110 may be electrically connected to the first integrated circuit IC1. When viewed in a plan view, the center pads 110 may be disposed on the center area CA.

The redistribution layers 130 may be disposed on the center pads 110. The redistribution layers 130 may include bonding pad portions 135c. The bonding pad portions 135c may be electrically connected to the first integrated circuit IC1 via the center pads 110. The bonding pad portions 135c may be provided on the first and second peripheral areas PA1 and PA2. The bonding pad portions 135c may be exposed to the outside. The redistribution layers 130 may apply signals from the first and second peripheral areas PA1 and PA2 to the center pads 110 of the center area CA through the bonding pad portions 135c.

The inventive concepts are not limited to the illustrated example of the center pads 110 and the redistribution layers 130, and example embodiments of the inventive concepts may be variously changed in consideration of a type or use of a semiconductor package.

The first semiconductor chip 20 may be one of memory chips (e.g., DRAM chip or FLASH memory chip). The first integrated circuit IC1 may include memory cells for storing data and a control and/or power circuit for controlling operations of the memory cells.

The first semiconductor chip 20 may be attached to the package substrate 10 using a first adhesive layer 15. The first adhesive layer 15 may be an insulating layer or a tape, which contains, for example, an epoxy or silicone-based material.

Wires 8 may electrically connect the bonding pad portions 135c of the first semiconductor chip 20 to the second outer pads 6 of the package substrate 10, respectively. The first semiconductor chip 20 may communicate with an external controller (not shown) through the wires 8. The wires 8 may transmit various data (e.g., control signals containing address and command data, voltage signals, and/or any other data) to the first semiconductor chip 20 from the controller. Further, the wires 8 may transmit data, which are read out from the memory cells of the first semiconductor chip 20, to the controller.

A mold layer 9 may be provided on the package substrate 10 to cover the first semiconductor chip 20 and the wires 8. The mold layer 9 may protect the first semiconductor chip 20 and the wires 8 against external environment, The mold layer 9 may include an epoxy molding compound material.

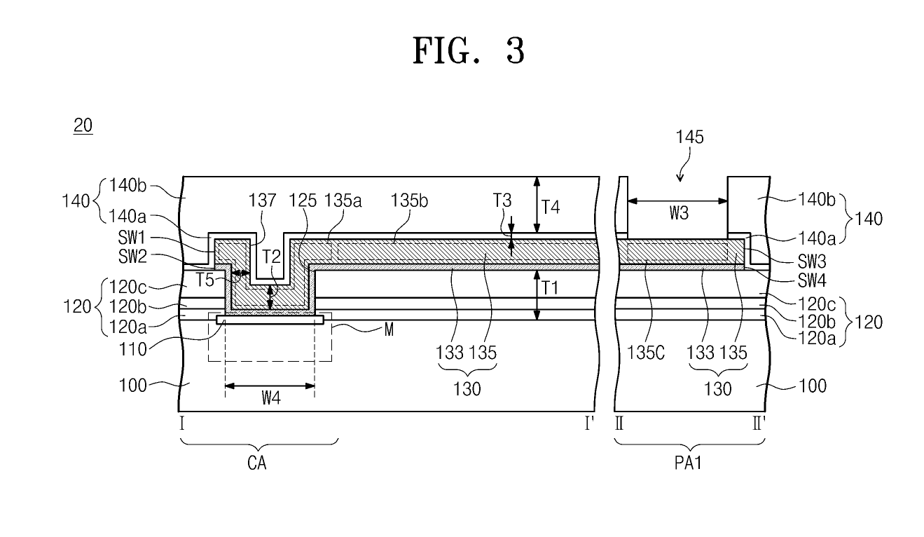

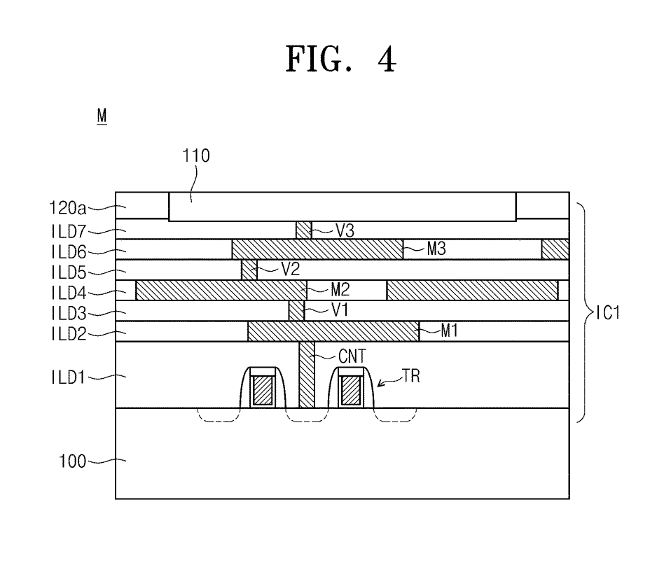

FIG. 3 is a sectional view of sections, which are respectively taken along lines I-I′ and II-II′ of FIG. 2, and illustrates a first semiconductor chip according to an example embodiment of the inventive concepts. FIG. 4 is an enlarged sectional view of a region M of FIG. 3. In the following description, the first semiconductor chip 20 will be described in more detail, without repeating an overlapping description of the semiconductor package previously described with reference to FIGS. 1 and 2.

Referring to FIGS. 2 through 4, the center pads 110 may be disposed on the center area CA of a semiconductor substrate 100. The semiconductor substrate 100 may be, for example, a silicon water, a germanium wafer, or a silicon-germanium wafer. The center pads 110 may be arranged to form two columns within the center area CA, but the inventive concepts may not be limited thereto. The center pads 110 may be formed of or include a conductive material (e.g., aluminum (Al)). At least one of the center pads 110 may have a first width W1, when measured in a first direction D1 parallel to a top surface of the semiconductor substrate 100. In some example embodiments, the first width W1 may range from about 5 μm to about 50 μm. Hereinafter, one of the center pads 110 will be described as an example of the center pads 110, for concise description.

The center pad 110 may be electrically connected to the first integrated circuit IC1 in the first semiconductor chip 20. Referring back to FIG. 4, the first integrated circuit IC1 may be disposed on the semiconductor substrate 100. The first integrated circuit IC1 may include a plurality of transistors TR, a plurality of metal layers M1-M3, and a plurality of vias V1-V3.

Each of the transistors TR may include a gate electrode and impurity regions provided at both side of the gate electrode. The impurity regions may be doped regions, which may be formed by injecting impurities into the semiconductor substrate 100. Each of the transistors TR may be used as a part of the memory cells or as a part of the control and/or power circuit for controlling operations of the memory cells.

First to seventh interlayered insulating layers ILD1-ILD7 may be sequentially stacked on the semiconductor substrate 100. The first interlayered insulating layer ILD1 may cover the transistors TR. A contact CNT may pass through the first interlayered insulating layer ILD1 and may be connected to one of the impurity regions of the transistors TR.

A first metal layer M1, a second metal layer M2, and a third metal layer M3 may be provided in the second interlayered insulating layer ILD2, the fourth interlayered insulating aver ILD4, and the sixth interlayered insulating layer ILD6, respectively. The center pad 110 may be provided on the seventh interlayered insulating layer ILD7. A first via V1 may be provided between the first and second metal layers M1 and M2, a second via V2 may be provided between the second and third metal layers M2 and M3, and a third via V3 may be provided between the third metal layer M3 and the center pad 110. The center pad 110 may be electrically connected to the transistors TR through the metal layers (M1-M3) and the vias V1-V3.

Referring back to FIGS. 2 and 3, a lower insulating structure 120 may be disposed on a top surface of the semiconductor substrate 100. The lower insulating structure 120 may partially cover the center pad 110. The lower insulating structure 120 may have a first thickness T1. As an example, the first thickness T1 may range from about 1 μm to about 12 μm.

Contact hole 125 may penetrate the lower insulating structure 120 and expose the remaining portion of the center pad 110. The contact hole 125 may have a fourth width W4, when measured in the first direction D1. The fourth width W4 may be smaller than the first width W1. For example, the fourth width W4 may range from about 5 μm to about 50 μm.

The lower insulating structure 120 may include first to third lower insulating layers 120a, 120b, and 120c, which are sequentially stacked on the semiconductor substrate 100. For example, the second lower insulating layer 120b may be interposed between the first and third lower insulating layers 120a and 120c. Here, the third lower insulating layer 120c may have a thickness greater than the first lower insulating layer 120a and/or the second lower insulating layer 120b.

Each of the first to third lower insulating layers 120a, 120b, and 120c may be formed of or include an inorganic insulating layer (e.g., silicon nitride, silicon oxide, or silicon oxynitride). In the case where a conductive pattern 135 is formed by a subsequent plating process, the lower insulating structure 120 may include a polymer layer (e.g., polyimide) because there is a difficulty to perform a metal plating process on an inorganic insulating layer. However, in the case that the conductive pattern 135 is formed by a deposition and patterning process, the lower insulating structure 120 may include an inorganic insulating layer. As an example, each of the first and third lower insulating layers 120a and 120c may include a silicon oxide layer, and the second lower insulating layer 120b may include a silicon nitride layer. Here, the first semiconductor chip 20 may be a DRAM chip.

The redistribution layer 130 may be provided on the lo insulating structure 120 to fill the contact hole 125 and be electrically connected to the center pad 110. In some example embodiments, as shown in FIG. 2, a plurality of redistribution layers 130 may he provided on the lower insulating structure 120. When viewed in a plan view, each of the redistribution layers 130 may be a line-shaped structure extending from the center pads 110 in the first direction D1. Some of the redistribution layers 130 may extend in a direction opposite to the first direction D1. For example, the redistribution layers 130 may extend from the center area CA to the first peripheral area PA1 or from the center area CA the second peripheral area PA2. At least one of the redistribution layers 130 may include a portion extending in a direction crossing the first direction D1. Accordingly, the redistribution layers 130 may be disposed to have end portions that are uniformly arranged on the first and second peripheral areas PA1 and PA2.

At least one of the redistribution layers 130 may have a second width W2, when measured in a second direction D2 crossing the first direction D1. In other words, the conductive pattern 135 of the at least one of the redistribution layers 130 may have the second width W2 in the second direction D2. The second direction D2 may be parallel to the top surface of the semiconductor substrate 100. As an example, each of the redistribution layers 130 may serve, for example, as a signal line, a power line, or a ground line. In some example embodiments, a width of each of the redistribution layers 130 may be in accordance with its assigned function. For example, the second width W2 may range from about 2 μm to about 200 μm.

The redistribution layer 130 may include a barrier pattern 133 and the conductive pattern 135 on the barrier pattern 133. The barrier pattern 133 may be interposed between the lower insulating structure 120 and the conductive pattern 135. The barrier pattern 133 may be overlapped with the conductive pattern 135, when viewed in a plan view. The barrier pattern 133 may be provided to prevent metallic elements from being diffused from the conductive pattern 135 to the lower insulating structure 120, and for example, may be formed of or include at least one of Ti, TiN, Ta, or TaN. Further, the harrier pattern 133 may be configured to have a good wetting property with respect to the lower insulating structure 120 thereunder.

The conductive pattern 135 may include a contact portion 135a filling the contact hole 125, a conductive line portion 135b provided on the lower insulating structure 120 and extended in the first direction D1, and a bonding pad portion 135c connected to the conductive line portion 135b. The contact portion 135a, the conductive line portion 135b, and the bonding pad portion 135c may be connected to form a single body (e.g., the conductive pattern 135).

The contact portion 135a may have a second thickness T2 at a bottom of the contact hole 125, when measured in a direction perpendicular to the top surface of the semiconductor substrate 100. Further, the contact portion 135a in the contact hole 125 may have a fifth thickness T5 in the first direction D1 or the second direction D2. Here, the second thickness T2 may be greater than the fifth thickness T5. For example, the second thickness T2 may range from about 1 μm to about 8 μm. The contact portion 135a filling the contact hole 125 may define a recess region 137.

The conductive line portion 135b may be positioned between the contact portion 135a and the bonding pad portion 135c. Similar to the redistribution layers 130 previously described with reference to FIG. 2, the conductive line portion 135b may be a line-shaped structure extending in the first direction D1. The conductive line portion 135b may electrically connect the bonding pad portion 135c on the first peripheral area PA1 to the contact portion 135a on the center area CA.

An end portion of the contact portion 135a may have a first sidewall SW1. An end portion of the barrier pattern 133 adjacent to the contact portion 135a may have a second sidewall SW2. Here, the first and second sidewalls SW1 and SW2 may be aligned to each other, when viewed in a plan view. An end portion of the bonding pad portion 135c may have a third sidewall SW3. Other end portion of the barrier pattern 133 adjacent to the bonding pad portion 135c may have a fourth sidewall SW4. Here, the third and fourth sidewalls SW3 and SW4 may be aligned to each other, when viewed in a plan view.

The conductive pattern 135 may include a metallic material, to facilitate subsequent deposition and patterning processes. As an example, the conductive pattern 135 may contain aluminum (Al).

An upper insulating structure 140 may be provided on the redistribution layer 130 and the lower insulating structure 120. The upper insulating structure 140 may include an upper insulating layer 140a and a polymer layer 140b, which may be sequentially stacked on the semiconductor substrate 100. The upper insulating layer 140a may cover the redistribution layer 130. For example, the upper insulating layer 140a may cover the first and third sidewalls SW1 and SW3 of the conductive pattern 135 and the second and fourth sidewalk SW2 and SW4 of the barrier pattern 133. The polymer layer 140b may be on the redistribution layer 130 with the upper insulating layer 140a interposed therebetween. The upper insulating structure 140 may protect the redistribution layer 130 against external environment and inhibit or prevent a short circuit from being formed between the redistribution layers 130.

A first opening 145 may penetrate the upper insulating structure 140 and expose the bonding pad portion 135c, For example, as shown in FIG. 2, a plurality of first openings 145 may be provided on the first and second peripheral areas PA and PA2 to expose the bonding pad portions 135c, respectively.

The first opening 145 may have a third width W3 in the first direction D1. The third width W3 may be greater than the fourth width W4. Accordingly, in a subsequent process, the wires 8 may be formed on the bonding pad portion 135c with relative ease. For example, the third width W3 may range from about 100 μm to about 300 μm.

In some example embodiments, the upper insulating layer 140a may include an inorganic insulating layer containing silicon (e.g., a silicon nitride layer, a silicon oxide layer, or a silicon oxynitride layer). The polymer layer 140b may be formed of or include an organic insulating layer (e.g., at least one of polyimide, fluoro carbon, resin, or synthetic rubber). The upper insulating layer 140a may have a third thickness T3, and the polymer layer 140b may have a fourth thickness T4. Here, the fourth thickness T4 may he greater than the third thickness T3. As an example, the third thickness T3 may range from about 0.1 μm to about 3 μm, and the fourth thickness T4 may range from about 0.3 μm to about 6 μm.

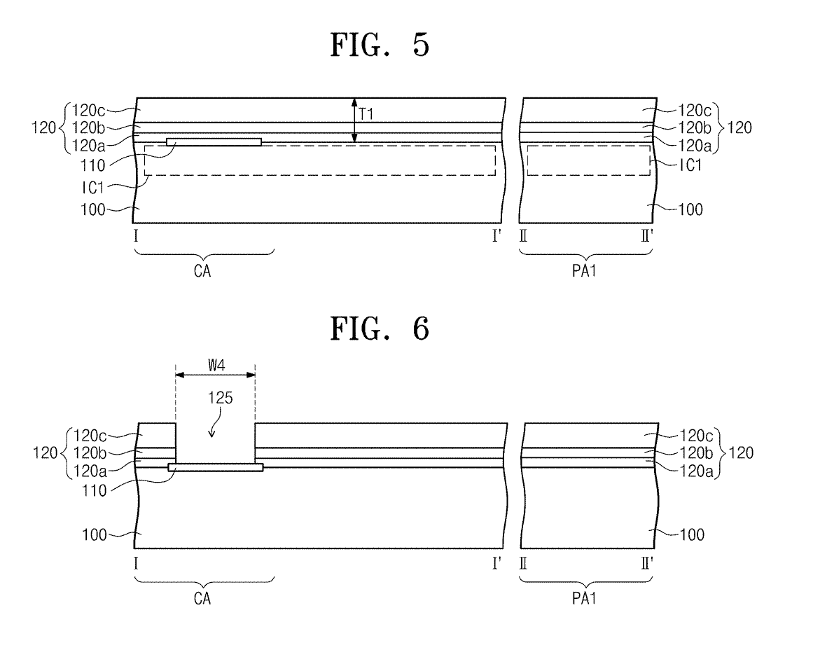

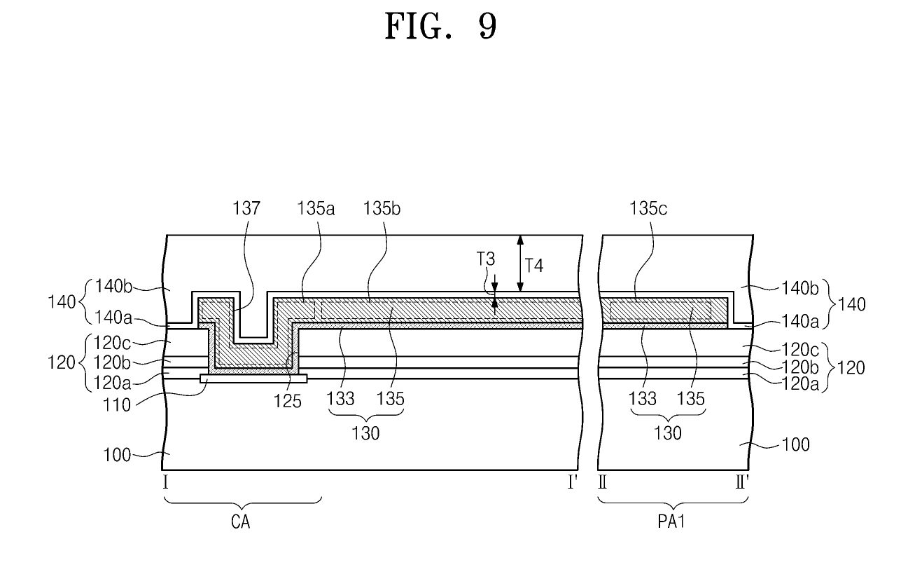

FIGS. 5 through 9 are sectional views, each of which illustrates sections taken along lines I-I′ and II-II′ of FIG. 2, and illustrate a method of fabricating a first semiconductor chip according to an example embodiment of the inventive concepts.

Referring to FIGS. 2 and 5, the first integrated circuit IC1 may be formed on the semiconductor substrate 100. The first integrated circuit IC1 may include a plurality of transistors TR, a plurality of metal layers M1-M3, and a plurality of vias V1-V3, as illustrated in FIG. 4.

The center pads 110 may be formed on the center area CA of the he semiconductor substrate 100. The center pads 110 may be electrically connected to the first integrated circuit IC1. Hereinafter, one of the center pads 110 will be described as an example of the center pads 110, for concise description.

The lower insulating structure 120 may be formed to cover the center pad 110. The lower insulating structure 120 may be formed to have the first thickness T1. As an example, the first thickness T1 may range from about 1 μm to about 12 μm.

For example, the lower insulating structure 120 may be formed by sequentially forming the first lower insulating layer 120a, the second lower insulating layer 120b, and the third lower insulating layer 120c on the top surface of the semiconductor substrate 100. At least one or each of the first to third lower insulating layers 120a, 120b, and 120c may be formed by an atomic layer deposition (ALD) process or a chemical vapor deposition (CVD) process. In some example embodiments the first and third lower insulating layers 120a and 120c may be formed of a silicon oxide layer and the second lower insulating layer 120b may be formed of a silicon nitride layer.

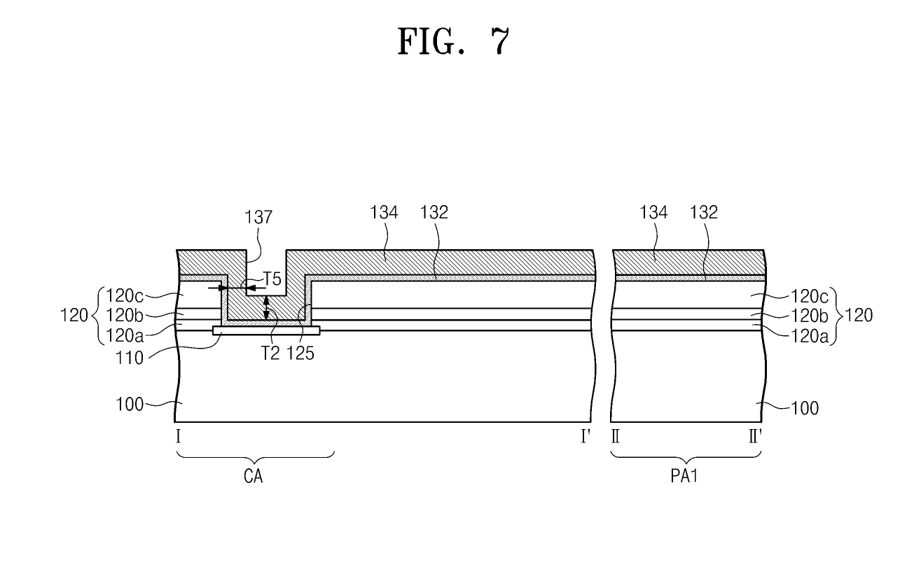

Referring to FIGS. 2 and 6, the lower insulating structure 120 may be patterned to form the contact hole 125 exposing the center pad 110. The patterning of the lower insulating structure 120 may include forming a first photoresist pattern (not shown) to have an opening overlapped with the center pad 110 in a plan view and etching the lower insulating structure 120 using the first photoresist pattern as an etch mask, The contact hole 125 may be formed to have the fourth width W4. For example, the fourth width W4 may range from about 5 μm to about 50 μm.

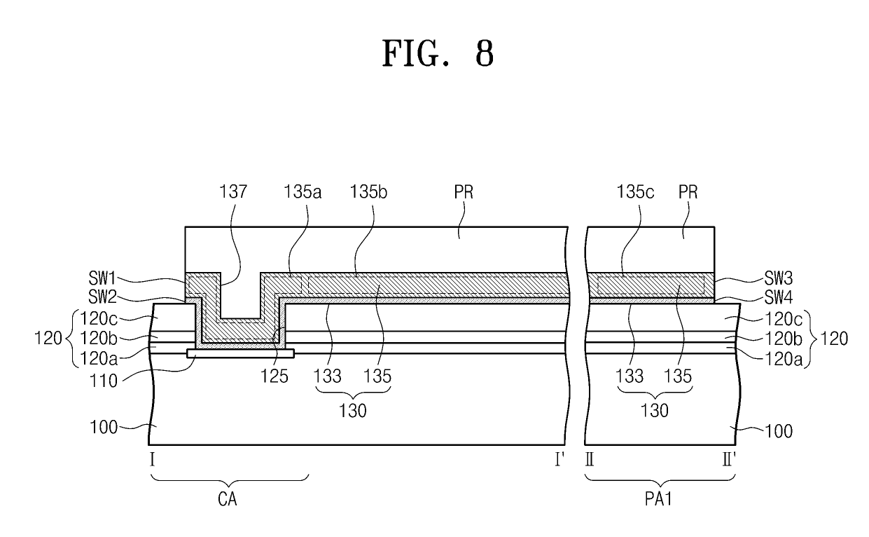

Referring to FIGS. 2 and 7, a barrier layer 132 may be formed on the top surface of the lower insulating structure 120 and a conductive layer 134 may be formed on the barrier layer 132. The barrier layer 132 and the conductive layer 134 may be formed to fill the contact hole 125. The barrier layer 132 may be formed to cover the center pad 110. The conductive layer 134 may be formed to have a thickness that is smaller than half a width of the contact hole 125, and thereby to define the recess region 137 on or in the contact hole 125.

The barrier layer 132 and the conductive layer 134 may be formed by a physical vapor deposition (PVD) process. When measured in a direction perpendicular to the top surface of the semiconductor substrate 100, the conductive layer 134 in the contact hole 125 may be formed to have the second thickness T2. The conductive layer 134 in the contact hole 125 may have the fifth thickness T5, when measured in the first direction D1 or the second direction D2. In the case where the conductive layer 134 is formed by a PVD process with a low step coverage property, the second thickness T2 may be greater than the fifth thickness T5.

In some example embodiments, the barrier layer 132 may be formed of or include at least one of Ti, TiN, Ta, or TaN. The conductive layer 134 may be formed of or include a metallic material (e.g., containing aluminum (Al)).

Referring to FIGS, 2 and 8, a second photoresist pattern PR may be formed on the conductive layer 134. In some example embodiments, a plurality of second photoresist patterns PR may define positions and shapes of the redistribution layers 130 described with reference to FIGS. 2 and 3.

The conductive layer 134 and the barrier layer 132 may be sequentially etched using the second photoresist pattern PR as an etch mask to form the redistribution layer 130. The the conductive layer 134 and the barrier layer 132 may be etched using a dry etching process. As an example, an etching gas containing BCl3 and/or SF6 may be used for the dry etching process, but the inventive concepts may not be limited thereto. The redistribution layer 130 may include the barrier pattern 133 and the conductive pattern 135 on the harrier pattern 133. The conductive pattern 135 may include the contact portion 135a, the conductive line portion 135b, and the bonding pad portion 135c.

In the case where the second photoresist pattern PR is used as a common mask for forming the conductive pattern 135 and the barrier pattern 133, the conductive pattern 135 and the barrier pattern 133 may overlap with each other when viewed in a plan view. For example, the first sidewall SW1 of the contact portion 135a may be aligned with the second sidewall SW2 of the barrier pattern 133 adjacent to the contact portion 135a. Also, the third sidewall SW3 of the bonding pad portion 135c may be aligned with the fourth sidewall SW4 of the barrier pattern 133 adjacent to the bonding pad portion 135c.

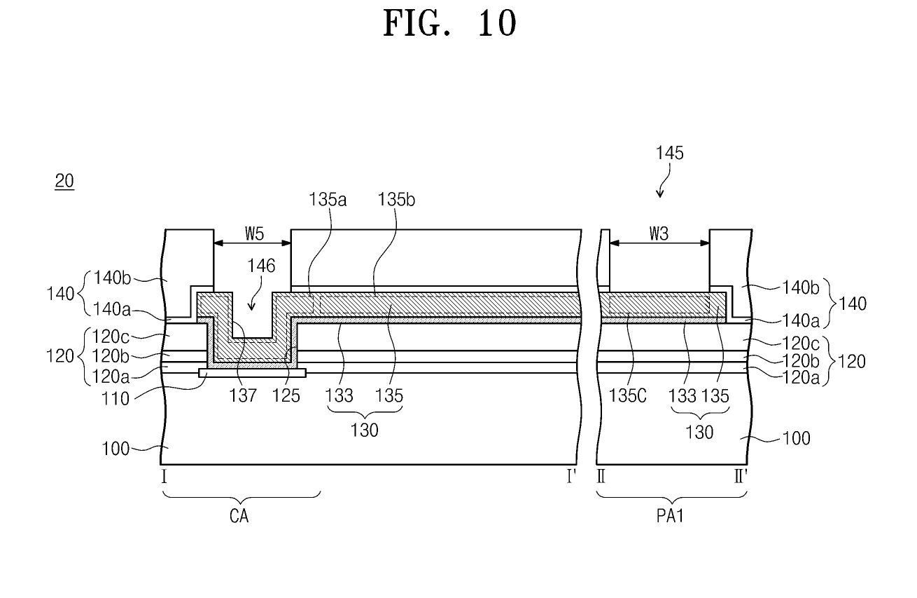

Referring to FIGS. 2 and 9, the second photoresist pattern PR may be removed. Thereafter, the upper insulating structure 140 may be formed on the redistribution layer 130 and the lower insulating structure 120.

The upper insulating structure 140 may be formed by sequentially forming the upper insulating layer 140a and the polymer layer 140b on the top surface of the semiconductor substrate 100. The upper insulating layer 140a may be formed by an ALD or CVD process. The polymer layer 140b may be formed by coating a polymer material (e.g., at least one of polyimide, fluoro carbon, resin, or synthetic rubber) or a precursor thereof on the upper insulating layer 140a. The upper insulating layer 140a may be formed to have the third thickness T3, and the polymer layer 140b may be formed to have the fourth thickness T4. Here, the fourth thickness T4 may be greater than the third thickness T3.

Referring back to FIGS. 2 and 3, the upper insulating structure 140 may be patterned to form the first opening 145 exposing the bonding pad portion 135c. The patterning of the upper insulating structure 140 may include forming a third photoresist pattern (not shown) to have an opening overlapping with the bonding pad portion 135c in a plan view and etching the upper insulating structure 140 using the third photoresist pattern as an etch mask. The first opening 145 may be formed to have the third width W3. For example, the third width W3 may range from about 100 μm to about 300 μm. In a subsequent package process, a wire bonding process may be performed on the bonding pad portion 135c exposed by the first opening 145.

According to some example embodiments of the inventive concepts, the redistribution layer 130 may be formed of a relatively inexpensive metal (e.g., aluminum), instead of gold or copper, and thus, a semiconductor chip and package may be manufactured at a reduced cost. Further, an existing metal-patterning system may be used to pattern the redistribution layer 130, and thus efficiency in the fabrication process may be improved.

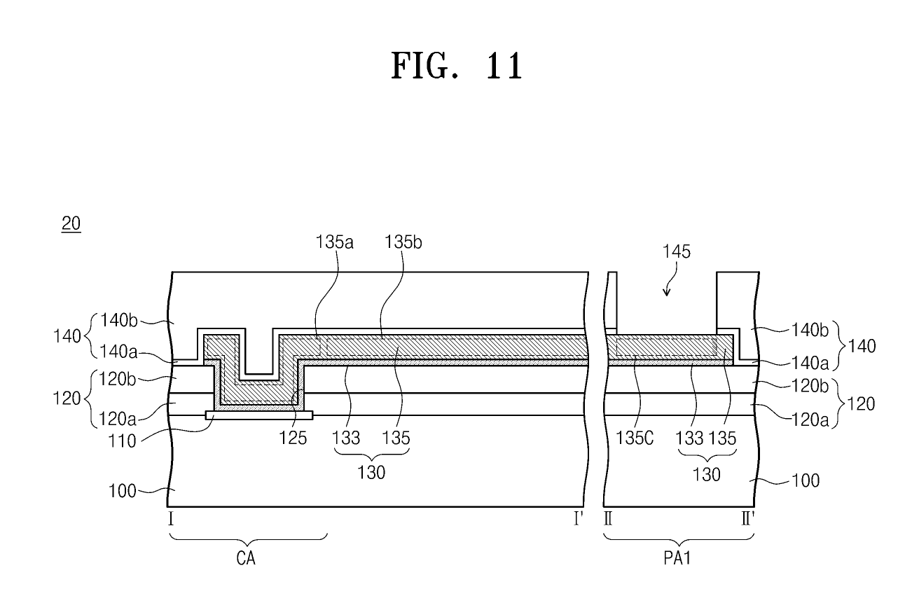

FIG. 10 is a sectional view of sections, which are respectively taken along lines and II-II′ of FIG. 2, and illustrates a first semiconductor chip according to an example embodiment of the inventive concepts. In the following description, an element of the first semiconductor chip previously described with reference to FIGS. 2 through 4 may be identified by a similar or identical reference number without repeating an overlapping description thereof, for the sake of brevity.

Referring to FIGS. 2 and 10, a second opening 146 may be provided to penetrate the upper insulating structure 140 and to expose the contact portion 135a. The second opening 146 may be provided to have a fifth width W5. In some example embodiments, the fifth width W5 may range from about 10 μm to about 100 μm.

Although not shown, an additional outer terminal may be connected to the contact portion 135a through the second opening 146, Accordingly, this structure of the contact portion 135a, in conjunction with the bonding pad portion 135c exposed by the first opening 145, may increase a degree of freedom in establishing a routing path with an external controller (not shown).

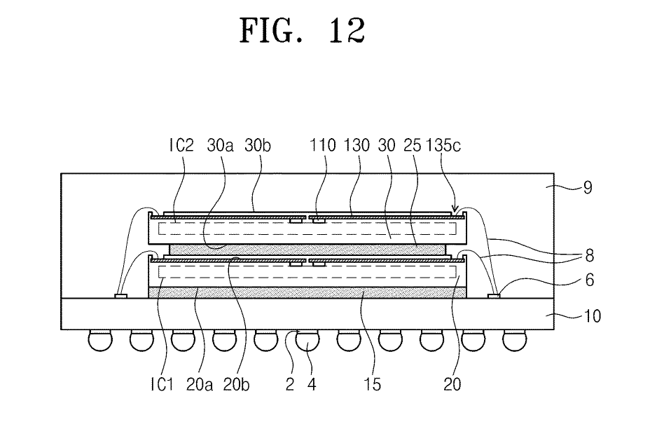

FIG. 11 is a sectional view of sections, which are respectively taken along lines and II-II′ of FIG. 2, and illustrates a first semiconductor chip according to an example embodiment of the inventive concepts. In the following description, an element of the first semiconductor chip previously described with reference to FIGS. 2 through 4 may be identified by a similar or identical reference number without repeating an overlapping description thereof, for the sake of brevity.

Referring to FIGS. 2 and 11, the lower insulating structure 120 may include the first and second lower insulating layers 120a and 120b, which may be sequentially stacked on the semiconductor substrate 100. At least one or each of the first and second lower insulating layers 120a and 120b may be formed of or include an inorganic insulating layer (e.g., silicon nitride, silicon oxide, or silicon oxynitride). For example, the first lower insulating layer 120a may include a silicon nitride layer, and the second lower insulating layer 120b may include a silicon oxide layer.

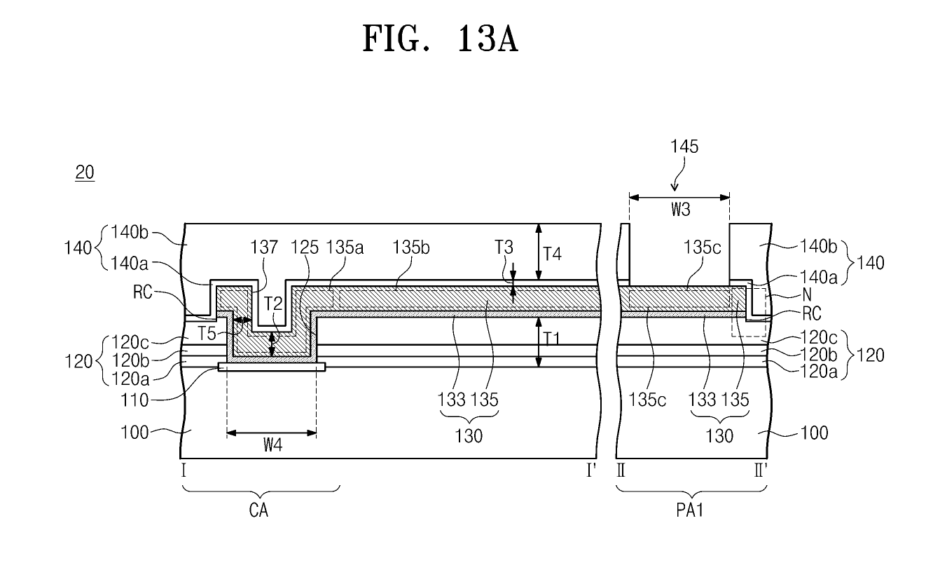

FIG. 12 is a sectional view illustrating a semiconductor package according to an example embodiment of the inventive concepts. In the following description, an element of the semiconductor package previously described with reference to FIGS. 1 and 2 may be identified by a similar or identical reference number without repeating an overlapping description thereof, for the sake of brevity.

Referring to FIG. 12, a first semiconductor chip 20 may be mounted on a package substrate 10, and a second semiconductor chip 30 may be mounted on the first semiconductor chip 20. The second semiconductor chip 30 may have a third surface 30a facing the first semiconductor chip 20 and a fourth surface 30b opposite to the third surface 30a.

The second semiconductor chip 30 may be a chip that is the same as or similar to the first semiconductor chip 20. For example, the second semiconductor chip 30 may be configured to have a second integrated circuit IC2, the center pads 110, and redistribution layers 130. The redistribution layers 130 may include bonding pad portions 135c, In some example embodiments, the second semiconductor chip 30 may be one of memory chips (e.g., DRAM chips or FLASH memory chips). The second integrated circuit IC2 may include memory cells for storing data and a control and/or power circuit for controlling operations of the memory cells.

The second semiconductor chip 30 may be attached to the first semiconductor chip 20 using a second adhesive layer 25. The second adhesive layer 25 may be an insulating layer or a tape, which contains, for example, an epoxy or silicone-based material. The second adhesive layer 25 may have a top surface positioned at a level higher than the topmost level of wires 8 connected to the first semiconductor chip 20.

The wires 8 may respectively connect the bonding pad portions 135c of the second semiconductor chip 30 to second outer pads 6 of the package substrate 10. The second semiconductor chip 30 may communicate with an external controller (not shown) through the wires 8.

The mold layer 9 may be provided on the package substrate 10 to cover the first and second semiconductor chips 20 and 30 and the wires 8. The mold layer 9 may protect the first and second semiconductor chips 20 and 30 and the wires 8 against external environment.

In some example embodiments, the semiconductor package may further include at least one semiconductor chip disposed on the second semiconductor chip 30, in addition to the first and second semiconductor chips 20 and 30.

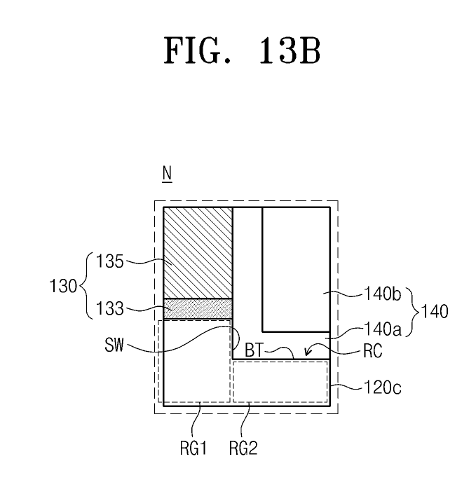

FIG. 13A is a sectional view of sections, which are respectively taken along lines I-I′ and II-II′ of FIG. 2, and illustrates a first semiconductor chip according to some embodiments of the inventive concept. FIG. 13B is an enlarged sectional view of a region N of FIG. 13A. In the following description, an element of the first semiconductor chip previously described with reference to FIGS. 2, 3, and 4 may be identified by a similar or identical reference number without repeating an overlapping description thereof, for the sake of brevity.

Referring to FIGS. 2, 13A, and 13B, the third lower insulating layer 120c may be provided to define a recess region RC. The recess region RC may be formed on entire areas including the center area CA and the peripheral areas PA1 and PA2 of the first semiconductor chip 20. On the other hand, the recess region RC may not be formed under the redistribution layer 130. When viewed in a plan view, the recess region RC may be spaced apart from the redistribution layer 130. In other words, the recess region RC may not be overlapped with the redistribution layer 130, when viewed in a plan view.

Referring back to FIG. 13B, the recess region RC may have a bottom surface 13T, which is positioned at a lower level than that of a top surface of the third lower layer 120c provided under the redistribution layer 130. The upper insulating layer 140a may be provided to directly cover a sidewall SW and the bottom surface BT of the recess region RC.

For example, the lower insulating structure 120 may include a first region RG1 and a second region RG2. When viewed in a plan view, the first region RG1 may be overlapped with the redistribution layer 130, and the second region RG2 may be overlapped with the recess region RC. Here, a top surface of the first region RG1 may he higher than a top surface of the second region RG2 (e.g., the bottom surface BT of the recess region RC).

Referring back to FIGS. 2, 8, 13A, and 13B, an upper portion of the lower insulating structure 120 may be etched during the process of etching the conductive layer 134 and the barrier layer 132, For example, during the etching process, the conductive layer 134 and the barrier layer 132 exposed by the second photoresist pattern PR may be removed, and then, an upper portion of the third lower insulating layer 120c thereunder may be partially etched. As a result, during the process of etching the redistribution layer 130, the recess region RC may be formed in the third lower insulating layer 120c.

According to example embodiments of the inventive concepts, a redistribution layer of a semiconductor chip may be formed by a deposition and patterning process, not by a plating process. Accordingly, a semiconductor chip may be economically fabricated. Furthermore, by providing multi-layered insulating structures on and under the redistribution layer, a semiconductor chip may exhibit higher or improved operation characteristics.

While some example embodiments of the inventive concepts have been particularly shown and described, it will be understood by one of ordinary skill in the art that variations in form and detail may be made therein without departing from the spirit and scope of the attached claims.

1. A semiconductor chip comprising:
an integrated circuit on a substrate;
a center pad on the substrate and electrically connected to the integrated circuit;
a lower insulating structure on the center pad, the lower insulating structure having a contact hole exposing the center pad, the lower insulating structure including a plurality of lower insulating layers sequentially stacked on the substrate;
a redistribution layer including a conductive pattern and a barrier pattern, the barrier pattern between the lower insulating structure and the conductive pattern, the conductive pattern including a contact portion, a bonding pad portion, and a conductive line portion, the contact portion filling the contact hole, the conductive line on the lower insulating structure and connecting the contact portion to the bonding pad portion; and
an upper insulating structure on the redistribution layer, the upper insulating structure having a first opening defined therein, the first opening exposing the bonding pad portion,
the upper insulating structure including an upper insulating layer and a polymer layer, the upper insulating layer covering the lower insulating structure and the redistribution layer, the polymer layer on the upper insulating layer.

2. The semiconductor package of claim 1, wherein a first end of the contact portion has a first sidewall, the first end of the contact portion being opposite to a second end of the contact portion at which the contact portion is connected to the conductive line portion, the barrier pattern adjacent to the first end of the contact portion has a second sidewall, and when viewed in a plan view, the second sidewall is aligned with the first sidewall.

3. The semiconductor chip of claim 2, wherein the upper insulating layer covers the first and second sidewalls.

4. The semiconductor chip of claim 1, wherein
the contact portion has a first thickness in a first direction perpendicular to a top surface of the substrate and a second thickness in a second direction parallel to the top surface of the substrate, and the first thickness is greater than the second thickness.

5. The semiconductor chip of claim 1, wherein the contact portion fills at least a portion of the contact hole, while defining a recess region.

6. The semiconductor chip of claim 1, wherein the upper insulating structure further includes a second opening, which exposes the contact portion.

7. The semiconductor chip of claim 1, wherein the center pad is electrically connected to the integrated circuit through a plurality of metal layers and a plurality of vias.

8. The semiconductor chip of claim 1, wherein, when viewed in a plan view,
the center pad is on a center area of the semiconductor chip, and the pad portion is on a peripheral area of the semiconductor chip.

9. The semiconductor chip of claim 1, wherein each of the lower insulating layers comprises at least one of a silicon nitride layer, a silicon oxide layer, or a silicon oxynitride layer.

10-12. (canceled)

13. The semiconductor chip of claim 1, wherein the conductive pattern includes aluminum.

14. The semiconductor chip of claim 1, wherein the upper insulating layer comprises at least one of a silicon nitride layer, a silicon oxide layer, or a silicon oxynitride layer.

15. The semiconductor chip of claim 1, wherein the polymer layer includes at least one of polyimide, fluoro carbon, resin, or synthetic rubber.

16-21. (canceled)

22. A semiconductor package, comprising:
a package substrate; and
at least one semiconductor chip on the package substrate and electrically connected to the package substrate through a wire, the at least one semiconductor chip including,
a first surface facing the package substrate and a second surface opposite to the first surface,
a center pad on the second surface,
a lower insulating structure having a contact hole exposing the center pad, the lower insulating structure including a plurality of sequentially-stacked lower insulating layers,
a conductive pattern including a contact portion, a conductive line portion, and a bonding pad portion, the contact portion filling the contact hole, the bonding pad portion in contact with the wire, and the conductive line portion on the lower insulating structure and connecting the contact portion to the bonding pad portion; and
an upper insulating structure on the conductive pattern, the upper insulating structure having an opening defined therein, the opening exposing the bonding pad portion, the upper insulating structure including,
an inorganic insulating layer on the lower insulating structure and the conductive pattern, the inorganic insulating layer containing silicon, and
a polymer layer on the inorganic insulating layer.

23. The semiconductor package of claim 22, wherein
the at least one semiconductor chip further includes an integrated circuit therein,
the integrated circuit is electrically connected to the center pad, and
the integrated circuit is electrically connected to the package substrate through the center pad, the conductive pattern, and the wire.

24. The semiconductor package of claim 22, wherein
the at least one semiconductor chip includes a plurality of semiconductor chips, which are sequentially stacked on the package substrate, and
at least one of the plurality of semiconductor chips is electrically connected to the package substrate through the bonding pad portion and the wire.

25. (canceled)

26. The semiconductor package of claim 22, wherein the lower insulating layers comprise,
a first lower insulating layer,
a second lower insulating layer on the first lower insulating layer and adjacent to the upper insulating structure, and
a third lower insulating layer between the first and second lower insulating layers.

27-31. (canceled)

32. A semiconductor package comprising:
a package substrate;
a semiconductor chip on the package substrate and including,
a chip pad electrically connected to an integrated circuit and exposed through a lower insulating structure,
a redistribution pattern connected to the chip pad at around a first end portion thereof and extending on the lower insulating structure, and
an upper insulating structure on the redistribution pattern and the lower insulating structure, the upper insulating structure including an opening at around a second end portion of the redistribution pattern, the opening exposing the redistribution pattern therethrough, the second end portion being opposite to the first end portion, a portion of the redistribution pattern exposed by the opening functioning as a pad portion; and
a wire connecting the exposed portion of the redistribution pattern of the semiconductor chip to the package substrate,
wherein
the lower insulating structure is between a chip substrate and the conductive pattern,
the lower insulating structure has a recess region formed in an upper portion thereof, and
when viewed in a plan view, the recess region is not overlapped with the conductive pattern.

33. The semiconductor package of claim 32, further comprising:
a barrier pattern between the lower insulating structure and the redistribution pattern, the barrier pattern inhibiting metallic elements diffusing from the redistribution pattern to the lower insulating structure.

34. The semiconductor package of claim 33, wherein
the first end portion of the redistribution pattern has a first sidewall,
the barrier pattern adjacent to the first end of the redistribution pattern has a second sidewall, the second sidewall is aligned with the first sidewall when viewed in a plan view, and
the upper insulating structure covers the first and second sidewalls.

35. The semiconductor package of claim 32, wherein the upper insulating structure includes an upper insulating layer and a polymer layer, the upper including layer covering the lower insulating structure and the redistribution pattern, the polymer layer on the upper insulating layer.
